(19) United States
(12) Patent Application Publication
(10) Pub. No.: US 2026/0215280 A1
(43) Pub. Date: Jul. 23, 2026

(54) SEMICONDUCTOR DEVICE

(71) Applicant: FUJI ELECTRIC CO., LTD., Kawasaki-shi (JP)

(72) Inventor: Motohito HORI, Matsumoto-city (JP)

(73) Assignee: FUJI ELECTRIC CO., LTD., Kawasaki-shi (JP)

(21) Appl. No.: 19/567,953

(22) Filed: Mar. 16, 2026

Related U.S. Application Data
(63) Continuation of application No. PCT/JP2025/002363, filed on Jan. 27, 2025.

(30) Foreign Application Priority Data
Mar. 15, 2024 (JP) 2024-041064

(51) Int. Cl. H10W 42/00; H10W 40/20; H10W 40/25

(52) U.S. Cl. CPC H10W 42/121; H10W 40/235; H10W 40/251; H10W 40/258

(57) ABSTRACT

A semiconductor device, including: an insulated circuit board having a metal plate on a lowermost side thereof; a stress relaxation layer formed on a lower surface of the metal plate and having a linear expansion coefficient larger than that of the metal plate; and a cooling module including a placement surface on which a lower surface of the stress relaxation layer is arranged via a thermally conductive adhesive.

### CROSS-REFERENCE TO RELATED APPLICATION(S)

This application is a continuation application of International Application PCT/JP2025/002363 filed on Jan. 27, 2025, which designated the U.S., and claims priority to Japanese Patent Application No. 2024-041064, filed on Mar. 15, 2024, the entire contents of which are incorporated herein by reference.

### BACKGROUND OF THE INVENTION

### 1. Field of the Invention

The embodiment discussed herein relates to a semiconductor device.

### 2. Background of the Related Art

A semiconductor device includes a semiconductor module and a cooling module on which the semiconductor module is arranged and a metal plate, a buffer layer, a bonding layer, and an insulating plate are sandwiched between the semiconductor module and the cooling module (see, for example, International Publication Pamphlet No. WO 2016/121159, Japanese Laid-open Patent Publication No. 2013-138267,Japanese Laid-open Patent Publication No. 2015-185688, and Japanese Laid-open Patent Publication No. 2015-018833).

### SUMMARY OF THE INVENTION

According to an aspect, there is provided a semiconductor device, including: an insulated circuit board including a metal plate on a lowermost side thereof; a stress relaxation layer formed on a lower surface of the metal plate and having a linear expansion coefficient larger than that of the metal plate; and a cooling module including a placement surface on which a lower surface of the stress relaxation layer is arranged via a thermally conductive adhesive.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a sectional side elevation view of a semiconductor device according to an embodiment;

FIG. 2 is a rear view of the semiconductor device according to the embodiment;

FIG. 3 is a flowchart indicative of a method for manufacturing the semiconductor device according to the embodiment;

FIG. 4 is a view for describing a semiconductor module assembly process according to the embodiment (part 1);

FIG. 5 is a view for describing the semiconductor module assembly process according to the embodiment (part 2);

FIG. 6 is a view for describing the semiconductor module assembly process according to the embodiment (part 3);

FIG. 7 is a sectional side elevation view of the semiconductor module according to the embodiment;

FIG. 8 is a sectional side elevation view of a semiconductor device taken as a reference example; and

FIGS. 9A and 9B are graphs indicative of the amount of a warp and tensile stress, respectively, according to the thickness of a stress relaxation layer.

### DETAILED DESCRIPTION OF THE INVENTION

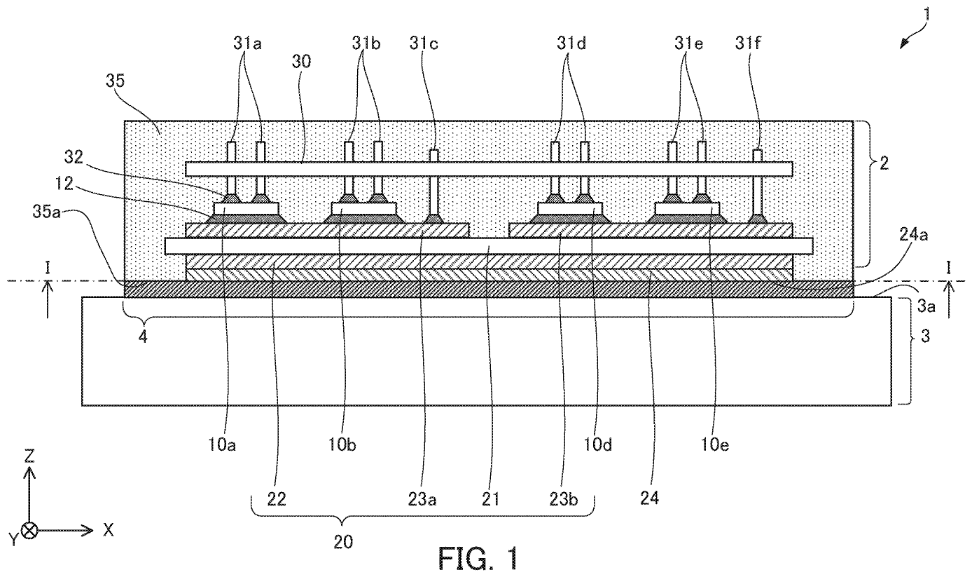

An embodiment will now be described with reference to the drawings. In the following description, a “front surface” or an “upper surface” represents an X-Y plane facing upward (+Z direction) in a semiconductor device 1 of FIG. 1. Similarly, an “upside” represents an upward direction (+Z direction) in the semiconductor device 1 of FIG. 1. A “back surface” or a “lower surface” represents the X-Y plane facing downward (−Z direction) in the semiconductor device 1 of FIG. 1. Similarly, a “downside” represents a downward direction (−Z direction) in the semiconductor device 1 of FIG. 1. The same directionality that is described above is meant in the other drawings at need. The term “higher” or “upper” represents a position on the upper side (+Z direction) in the semiconductor device 1 of FIG. 1. Similarly, the term “lower” or “under” represents a position on the lower side (−Z direction) in the semiconductor device 1 of FIG. 1. The terms “front surface”, “upper surface”, “upside” and “back surface”, “lower surface”, “downside” and “side surface” are mere expressions for convenience of specifying a relative positional relationship, and do not limit the technical idea of the present disclosure. For example, “upside” or “downside” does not always mean the vertical direction with respect to the ground. That is to say, a direction represented by the “upside” or “downside” is not limited to the gravity direction. In addition, in the following description, “main component” represents a case where 80 vol % or more is contained. Furthermore, “substantially the same” may be within a range of ±10%. In addition, “perpendicular”, “orthogonal”, and “parallel” may be within a range of ±10°.

### EMBODIMENT

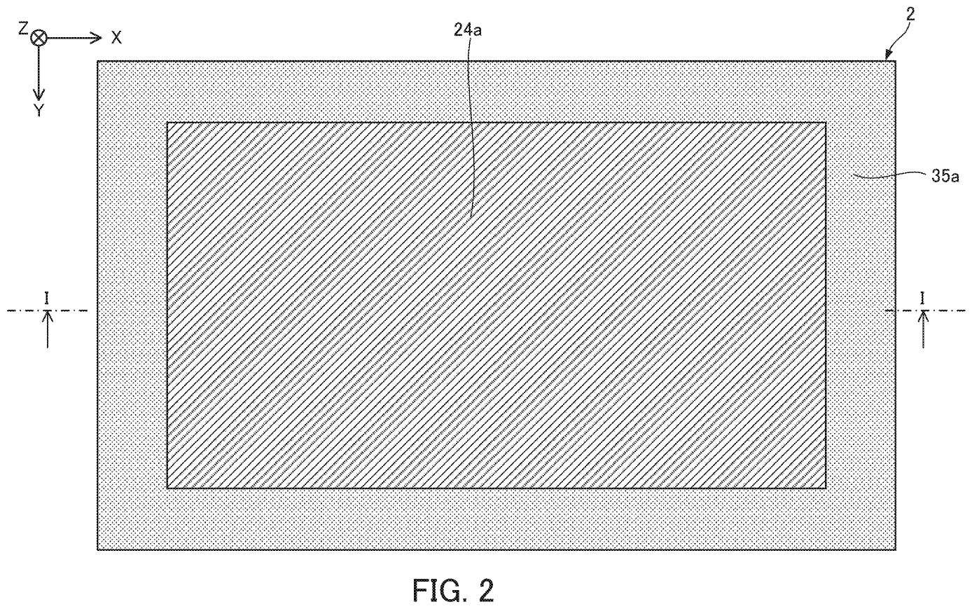

The semiconductor device 1 according to an embodiment will be described with reference to FIGS. 1 and 2. FIG. 1 is a sectional side elevation view of a semiconductor device according to an embodiment. FIG. 2 is a rear view of the semiconductor device according to the embodiment. FIG. 2 is a sectional view of the semiconductor device 1 of FIG. 1 taken along the plane I-I indicated by a dot-dash line. That is to say, FIG. 2 is a plan view of a placement surface 3a of a cooling module 3 on which a bonding member 4 is formed. FIG. 1 illustrates a section taken along the dot-dash line I-I in FIG. 2 and viewed in the +Y direction.

The semiconductor device 1 includes a semiconductor module 2, the cooling module 3, and the bonding member 4 by which the semiconductor module 2 and the cooling module 3 are bonded together. The semiconductor device 1 may include needed components in addition to these components.

The semiconductor module 2 includes semiconductor chips 10a, 10b, 10d, and 10e, an insulated circuit board 20, a printed-circuit board 30, and a stress relaxation layer 24 and includes a sealing member 35 that seals these components. The semiconductor chips 10a, 10b, 10d, and 10e may be power metal-oxide-semiconductor field-effect transistors (MOSFETs) containing silicon carbide as a main component. In the power MOSFET, a body diode may function as a free wheeling diode (FWD). Each of the semiconductor chips 10a, 10b, 10d, and 10e has, for example, an input electrode (drain electrode) as a main electrode on the back surface and has an output electrode (source electrode) as a main electrode and a control electrode (gate electrode) on the front surface. The control electrode may be formed at the center of one side portion or at a position shifted from the center along a side portion of the front surface of each of the semiconductor chips 10a, 10b, 10d, and 10e.

Alternatively, each of the semiconductor chips 10 a, 10 b, 10d, and 10e may include a switching element containing silicon as a main component. The switching element is, for example, a reverse-conducting insulated gate bipolar transistor (RC-IGBT). The RC-IGBT is a semiconductor element in which an IGBT and an FWD are arranged in inverse parallel in one chip.

In this case, each of the semiconductor chips 10a, 10b, 10d, and 10e has an input electrode (collector electrode) as a main electrode on the back surface and has an output electrode (emitter electrode) as a main electrode and a control electrode (gate electrode) on the front surface. The control electrode may be formed at the center of one side portion or at a position shifted from the center along a side portion of the front surface of each of the semiconductor chips 10a, 10b, 10d, and 10e. This is the same with the power MOSFET.

Furthermore, for example, the semiconductor chips 10a, 10b, 10d, and 10e each contain silicon as a main component and may be semiconductor chips each including a set of switching elements and a set of diode elements. Specifically, the semiconductor chips 10a and 10d may include switching elements and the semiconductor chips 10b and 10e may include diode elements. The switching element is, for example, a power MOSFET or an IGBT. A semiconductor chip including a switching element has, for example, an input electrode (drain electrode in a power MOSFET or a collector electrode in an IGBT) as a main electrode on the back surface and has a gate electrode as a control electrode and an output electrode (source electrode in the power MOSFET or an emitter electrode in the IGBT) as a main electrode on the front surface. In addition, as the diode element, for example, a Schottky barrier diode (SBD) or a P-intrinsic-N (PiN) diode is used as the FWD. A semiconductor chip including a diode element has an output electrode (cathode electrode) as a main electrode on the back surface and has an input electrode (anode electrode) as a main electrode on the front surface.

The semiconductor chips 10a and 10b and the semiconductor chips 10d and 10e may be bonded to conductive circuit patterns 23a and 23b, respectively, described later by solder 12. The solder 12 is made of a solder component. The solder component is a substance constituting the solder 12 and includes lead-free solder containing a predetermined alloy as a main component. The predetermined alloy contains tin. Such an alloy is, for example, at least one of a tin-silver alloy, a tin-silver-copper alloy, a tin-zinc-bismuth alloy, a tin-copper alloy, a tin-silver-indium-bismuth alloy, and a tin-antimony alloy. Furthermore, such a solder component may contain an additive. The additive is, for example, nickel, germanium, cobalt, or silicon. Therefore, the solder component is, for example, tin and at least one of silver, zinc, copper, bismuth, indium, and antimony. Furthermore, the solder component may contain, for example, at least one of nickel, germanium, cobalt, and silicon. Moreover, a sintered body may be used instead of the solder 12. A sintered material used for performing bonding by the sintered body is, for example, powder of silver, iron, copper, aluminum, titanium, nickel, tungsten, or molybdenum.

The insulated circuit board 20 includes an insulating plate 21, a metal plate 22, and the conductive circuit patterns 23a and 23b. The insulating plate 21 and the metal plate 22 have a rectangular shape in plan view. Furthermore, corner portions of the insulating plate 21 and the metal plate 22 may be R-chamfered or C-chamfered. The size of the metal plate 22 is smaller than the size of the insulating plate 21 in plan view and the metal plate 22 is formed inside the insulating plate 21.

The insulating plate 21 is, for example, a ceramic board. The ceramic board is made of a ceramic having good thermal conductivity. The ceramic is made of, for example, a material containing aluminum oxide, aluminum nitride, or silicon nitride as a main component. Furthermore, the insulating plate 21 has a rectangular shape in plan view. The

insulated circuit board 20 including the insulating plate 21 having the above structure is, for example, a direct copper bonding (DCB) substrate or an active metal brazed (AMB) substrate.

Alternatively, the insulating plate 21 may be made of resin. The resin may be a material having low thermal resistance and a high insulating property. the resin is, for example, a thermosetting resin. The thermosetting resin may further contain a filler. The thermal resistance of the insulating plate 21 is further reduced by controlling a material and the content of the filler.

The thermosetting resin is, for example, at least one of epoxy resin, cyanate resin, polyimide resin, benzoxazine resin, unsaturated polyester resin, phenol resin, melamine resin, silicone resin, and maleimide resin. The filler is at least one of an oxide and a nitride. The oxide is, for example, silicon oxide or aluminum oxide. The nitride is, for example, silicon nitride, aluminum nitride, or boron nitride. Furthermore, hexagonal boron nitride may be used as the filler.

The thickness of the insulating plate 21 depends on a rated voltage of the semiconductor device 1. That is to say, as the rated voltage of the semiconductor device 1 becomes higher, the thickness of the insulating plate 21 needs to be increased. On the other hand, the thermal resistance needs to be reduced by making the insulating plate 21 as thin as possible.

The metal plate 22 is made of metal, such as copper, aluminum, or an alloy containing at least one of them, having excellent thermal conductivity. In this case, copper is contained. In addition, in order to improve corrosion resistance, plating treatment may be performed on the surfaces of the metal plate 22. A plating material in this case contains nickel. The plating material is, for example, nickel, a nickel-phosphorus alloy, or a nickel-boron alloy.

The semiconductor chips 10a and 10b and the semiconductor chips 10d and 10e are arranged on the conductive circuit patterns 23a and 23b, respectively. The conductive circuit patterns 23a and 23b are formed over the entire surface of the insulating plate 21 except for an edge portion thereof. Preferably, in plan view, end portions of the conductive circuit patterns 23a and 23b facing the outer periphery of the insulating plate 21 are aligned with end portions of the metal plate 22 on the outer periphery side. Therefore, in the insulated circuit board 20, stress balance between the conductive circuit patterns 23a and 23b on the front surface of the insulating plate 21 and the metal plate 22 on the back surface of the insulating plate 21 is maintained. This further suppresses damage, such as an excessive warp or a crack, to the insulating plate 21.

The conductive circuit patterns 23a and 23b are made of a material, such as copper, aluminum, or an alloy containing at least one of them, having excellent electrical conductivity. The conductive circuit patterns 23a and 23b may be plated with a material having excellent corrosion resistance. The material is, for example, nickel, a nickel-phosphorus alloy, or a nickel-boron alloy. The conductive circuit patterns 23a and 23b are obtained by forming a metal plate on the front surface of the insulating plate 21 and performing processing, such as etching, on the metal plate. Alternatively, the conductive circuit patterns 23a and 23b cut out from a metal plate in advance may be bonded to the front surface of the insulating plate 21. The conductive circuit patterns 23a and 23b included in semiconductor device 1 of the present embodiment are merely examples. The number, shape, size, and the like of conductive circuit patterns may be properly selected at need.

The printed-circuit board 30 includes an insulating layer and a plurality of upper circuit pattern layers formed on the front surface of the insulating layer. Furthermore, the printed-circuit board 30 may include a plurality of lower circuit pattern layers on the back surface of the insulating layer. The printed-circuit board 30 is opposed to the front surface of the insulated circuit board 20 in plan view and in a side view. Furthermore, the printed-circuit board 30 is electrically connected to the output electrodes, the input electrodes, and the control electrodes of the semiconductor chips 10a, 10b, 10d, and 10e. Conductive posts 31a, 31b, 31d, and 31e illustrated in FIG. 1 are merely examples and conductive posts not illustrated in FIG. 1 may also be included. In addition, upper portions of the conductive posts 31a, 31b, 31d, and 31e and the conductive posts not illustrated in FIG. 1 are electrically connected to the upper circuit pattern layers and the lower circuit pattern layers of the printed-circuit board 30. Moreover, lower portions of the conductive posts 31a, 31b, 31d, and 31e and the conductive posts not illustrated in FIG. 1 are connected to the output electrodes and the control electrodes of the semiconductor chips 10a, 10b, 10d, and 10e by solder 32. A solder component of the solder 32 is also the same as the solder component of the solder 12. Furthermore, the above-described sintered body may be used instead of the solder 32.

For example, the printed-circuit board 30 is electrically connected to the output electrodes on the front surfaces of the semiconductor chips 10a and 10b through the conductive posts 31a and 31b. The printed-circuit board 30 is electrically connected to the output electrodes on the front surfaces of the semiconductor chips 10d and 10e through the conductive posts 31d and 31e.

The printed-circuit board 30 is electrically connected to the input electrodes on the back surfaces of the semiconductor chips 10a and 10b via a conductive post 31c and the conductive circuit pattern 23a. In addition, the printed-circuit board 30 is electrically connected to the input electrodes on the back surfaces of the semiconductor chips 10d and 10e via a conductive post 31f and the conductive circuit pattern 23b.

The printed-circuit board 30 is electrically connected to the control electrodes on the front surfaces of the semiconductor chips 10a and 10b via conductive posts (not illustrated). The printed-circuit board 30 is electrically connected to the control electrodes on the front surfaces of the semiconductor chips 10d and 10e via conductive posts (not illustrated).

The stress relaxation layer 24 is formed on the entire lower surface of the metal plate 22 of the insulated circuit board 20. The stress relaxation layer 24 is made of a material having a linear expansion coefficient larger than that of the metal plate 22 of the insulated circuit board 20. Furthermore, a material having high thermal conductivity is preferable. The material is, for example, aluminum. The stress relaxation layer 24 includes a heat dissipation surface 24a on the lower surface. The heat dissipation surface 24a may be approximately flat. The heat dissipation surface 24a is also a part of the lower surface of the semiconductor module 2. In addition, the heat dissipation surface 24a of the stress relaxation layer 24 is exposed from a sealing lower surface 35a of the sealing member 35 described later. At this time, the heat dissipation surface 24a of the stress relaxation layer 24 may protrude outward from the sealing lower surface 35a of the sealing member 35 or may be flush with the sealing lower surface 35a of the sealing member 35. In the present embodiment, the heat dissipation surface 24a of the stress relaxation layer 24 is flush with the sealing lower surface 35a of the sealing member 35.

The sealing member 35 seals the whole of the insulated circuit board 20, the semiconductor chips 10a, 10b, 10d, and 10e, the printed-circuit board 30, and the stress relaxation layer 24. For example, various terminals for input, output, and control may protrude from an upper surface of the sealing member 35 at need. The sealing member 35 may have, for example, a rectangular parallelepiped shape and includes a flat sealing lower surface 35a. The heat dissipation surface 24a of the stress relaxation layer 24 is exposed from the sealing lower surface 35a of the sealing member 35.

The sealing member 35 may be a thermosetting resin containing a filler. That is to say, the sealing member 35 contains an insulating filler and resin (thermosetting resin) described later as main components. In this case, the thermosetting resin is, for example, epoxy resin, phenol resin, maleimide resin, or polyester resin. The filler may contain, as a main component, an insulating ceramic having high thermal conductivity. The filler is, for example, silicon oxide, aluminum oxide, boron nitride, or aluminum nitride.

The cooling module 3 includes, on its upper surface, the placement surface 3a on which the heat dissipation surface 24a of the semiconductor module 2 is arranged. The placement surface 3a is wider than the sealing lower surface 35a, which is the back surface of the semiconductor module 2, and is approximately flat. The cooling module 3 may be, for example, a heat dissipation base including heat dissipation fins or a cooling device in which a refrigerant circulates. At least a portion of the cooling module 3 including the placement surface 3a on which the semiconductor module 2 is arranged is made of metal, such as copper, aluminum, or an alloy containing at least one of them, having excellent thermal conductivity. In this case, copper is contained. In addition, in order to improve corrosion resistance, plating treatment may be performed on the surface of the placement surface 3a of the cooling module 3. A plating material in this case contains nickel. The plating material is, for example, nickel, a nickel-phosphorus alloy, or a nickel-boron alloy.

The bonding member 4 is formed between the heat dissipation surface 24a of the stress relaxation layer 24 of the semiconductor module 2 and the placement surface 3a of the cooling module 3. The shape and size of the bonding member 4 in plan view in the −Z direction approximately match the shape and size of the lower surface of the semiconductor module 2. That is to say, the bonding member 4 is in contact with the heat dissipation surface 24a of the stress relaxation layer 24 of the semiconductor module 2 and the sealing lower surface 35a around the heat dissipation surface 24a.

The bonding member 4 is a thermally conductive adhesive and may be made of a material having thermal conductivity, an insulating property, and an adhesive property. The thermal conductivity may be, for example, 10 W/(m·K) or more. A material may be selected so that the thermal conductivity in this range is obtained. Furthermore, adhesive strength is, for example, 10 MPa or more. The adhesive strength is tensile adhesive strength. In addition, bonding temperature may be 200° C. or less. The bonding member 4 may contain, for example, resin as a main component and a filler. The resin may be, for example, epoxy-based resin. The filler contains, for example, a ceramic or metal as a main component. The ceramic has high thermal conductivity and is, for example, silicon oxide, aluminum oxide, boron nitride, or aluminum nitride. If the filler is a ceramic, then the bonding member 4 containing the filler secures thermal conductivity in addition to the adhesive property. The metal has high thermal conductivity and electrical conductivity and is, for example, silver, copper, gold, nickel, chromium, aluminum, or an alloy containing at least one of them. If the filler is metal, then the bonding member 4 containing the filler secures thermal conductivity in addition to the adhesive property and also has electrical conductivity. Because the bonding member 4 has electrical conductivity, the stress relaxation layer 24 and the cooling module 3 described later have the same potential. As a result, it is possible to prevent the occurrence of discharge between the semiconductor module 2 (stress relaxation layer 24) and the cooling module 3. Outer corner portions of the bonding member 4 may be R-chamfered. This prevents stress concentration on the corner portions. Accordingly, it is possible to suppress the occurrence of peeling of the bonding member 4 from the heat dissipation surface 24a and the placement surface 3a.

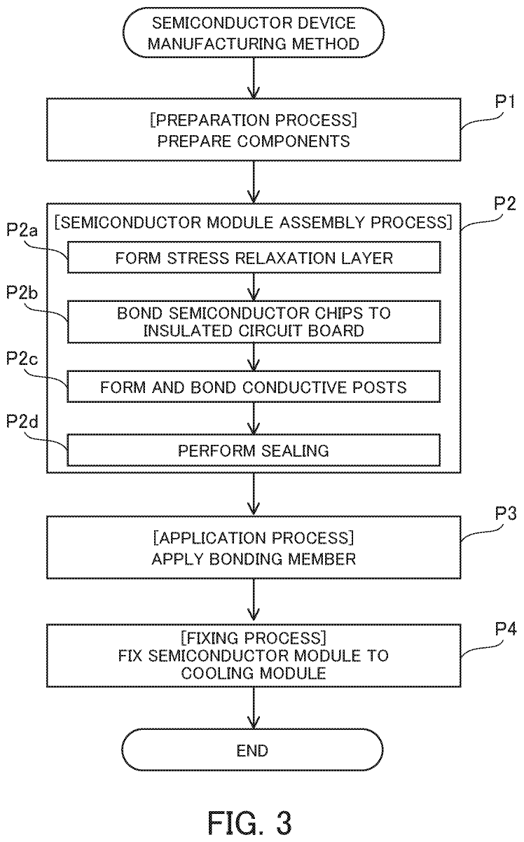

A method for manufacturing the semiconductor device 1 will now be described with reference to FIG. 3. FIG. 3 is a flowchart indicative of a method for manufacturing the semiconductor device according to the embodiment. First, a preparation process for preparing components of the semiconductor device 1 is performed (process P1). The components prepared in this process are, for example, the semiconductor chips 10a, 10b, 10d, and 10e, the insulated circuit board 20, the printed-circuit board 30 through which the conductive posts 31a, 31b, 31c, 31d, 31e, and 31f are formed, which are included in the semiconductor module 2, the sealing member 35, the bonding member 4, and a raw material for the stress relaxation layer 24. Furthermore, the components prepared in this process include the cooling module 3.

Components needed for manufacturing the semiconductor device 1 and not listed here may be prepared. In addition, a manufacturing apparatus used for manufacturing the semiconductor device 1 may also be prepared. The manufacturing apparatus is, for example, an application apparatus for applying solder or a molding apparatus for sealing with a sealing member.

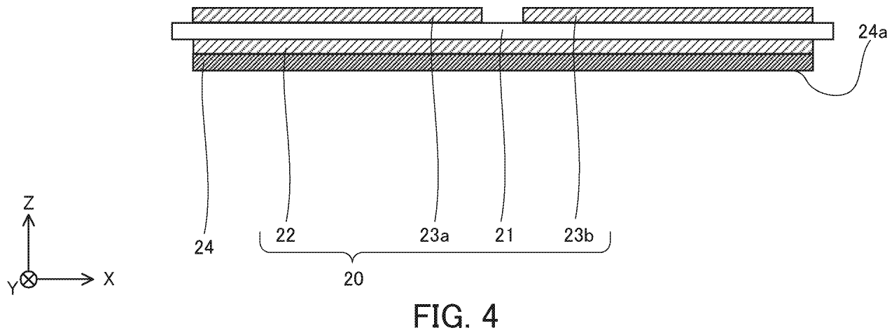

Next, a semiconductor module assembly process for assembling the semiconductor module 2 is performed (process P2). In the semiconductor module assembly process, the following steps are further performed. First, the stress relaxation layer 24 is formed on the insulated circuit board 20 (step P2a). Step P2a will be described with reference to FIG. 4. FIG. 4 is a view for describing the semiconductor module assembly process according to the embodiment.

Metal powder is thermally sprayed on the back surface of the metal plate 22 of the insulated circuit board 20. In this thermal spraying, for example, by a cold spraying method, metal powder is accelerated to a supersonic region and thermally sprayed in a solid phase state to form the stress relaxation layer 24 on the back surface of the metal plate 22. The cold spraying method is carried out at a lower temperature than the other thermal spraying. Therefore, oxidation of the metal plate 22 is prevented and the influence of heat on the insulated circuit board 20 is suppressed. By this thermal spraying, as illustrated in FIG. 4, the stress relaxation layer 24 is formed on the back surface of the metal plate 22 of the insulated circuit board 20.

Furthermore, the insulated circuit board 20 on which the stress relaxation layer 24 is formed may also be formed by the following method. For example, in the preparation process of process P1, a clad material including a metal plate of the same material as the metal plate 22 and a layer of the same material as the stress relaxation layer 24 formed on the back surface of the metal plate is prepared. The clad material is produced by roll-bonding the above-described layer to the above-described metal plate and performing heat treatment. By cutting this clad material into a desired size, a member in which the metal plate 22 and the stress relaxation layer 24 are laminated is obtained. The insulating plate 21 is formed on the front surface of the metal plate 22 of this member and the conductive circuit patterns 23a and 23b are formed on the front surface of the insulating plate 21. By doing so, as illustrated in FIG. 4, the insulated circuit board 20 on which the stress relaxation layer 24 is formed is obtained.

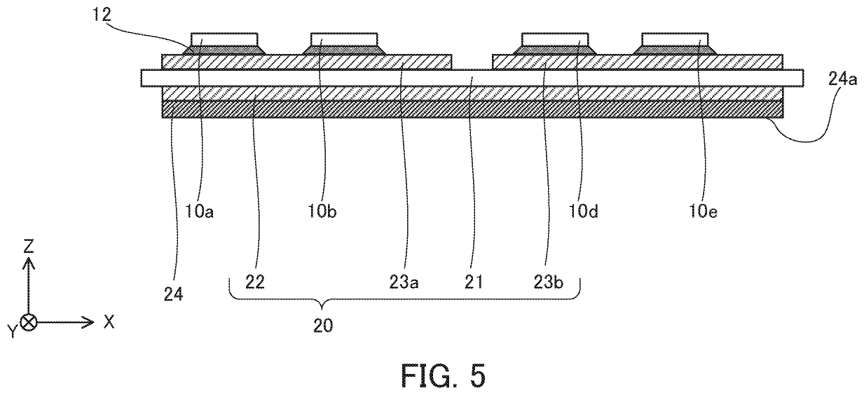

After that, the semiconductor chips 10 a, 10 b, 10 d, and 10e are bonded to the insulated circuit board 20 (step P2b). Step P2b will be described with reference to FIG. 5. FIG. 5 is a view for describing the semiconductor module assembly process according to the embodiment. The semiconductor chips 10a, 10b, 10d, and 10e are bonded to the conductive circuit patterns 23a and 23b, respectively, of the insulated circuit board 20 via the solder 12. At this time, conventional solder bonding is performed. As a result, as illustrated in FIG. 5, a structure is obtained in which the semiconductor chips 10a and 10b are bonded to the conductive circuit pattern 23a of the insulated circuit board 20 via the solder 12 and in which the semiconductor chips 10d and 10e are bonded to the conductive circuit pattern 23b of the insulated circuit board 20 via the solder 12.

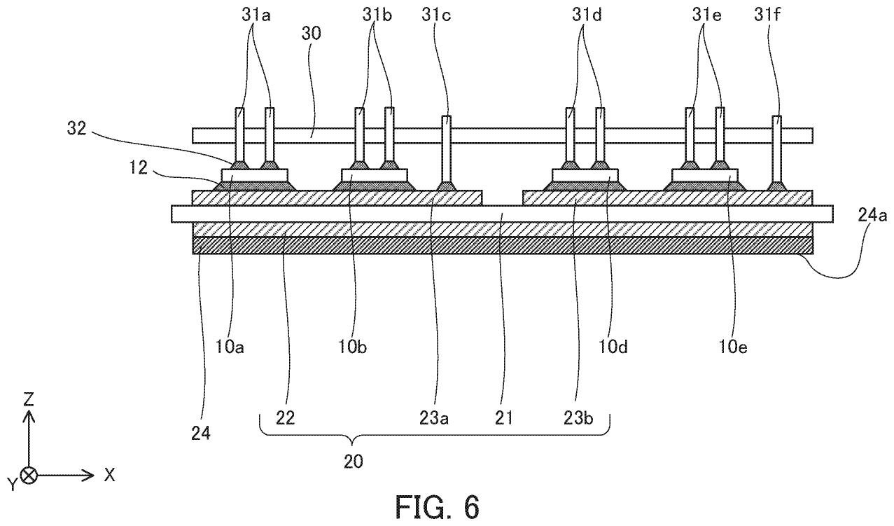

After that, the conductive posts 31a, 31b, 31c, 31d, 31e, and 31f of the printed-circuit board 30 are bonded to the semiconductor chips 10a and 10b, the conductive circuit pattern 23a of the insulated circuit board 20, the semiconductor chips 10d and 10e, and the conductive circuit pattern 23b of the insulated circuit board 20, respectively (step P2c). The step P2c will be described with reference to FIG. 6. FIG. 6 is a view for describing the semiconductor module assembly process according to the embodiment.

The conductive posts 31a, 31b, 31c, 31d, 31e, and 31f are formed in the printed-circuit board 30 in advance. The conductive posts 31a, 31b, 31c, 31d, 31e, and 31f are bonded by the solder 32 using the conventional solder bonding. As a result, as illustrated in FIG. 6, a structure in which the printed-circuit board 30 is fixed to the insulated circuit board 20 to which the semiconductor chips 10a, 10b, 10d, and 10e are bonded is obtained.

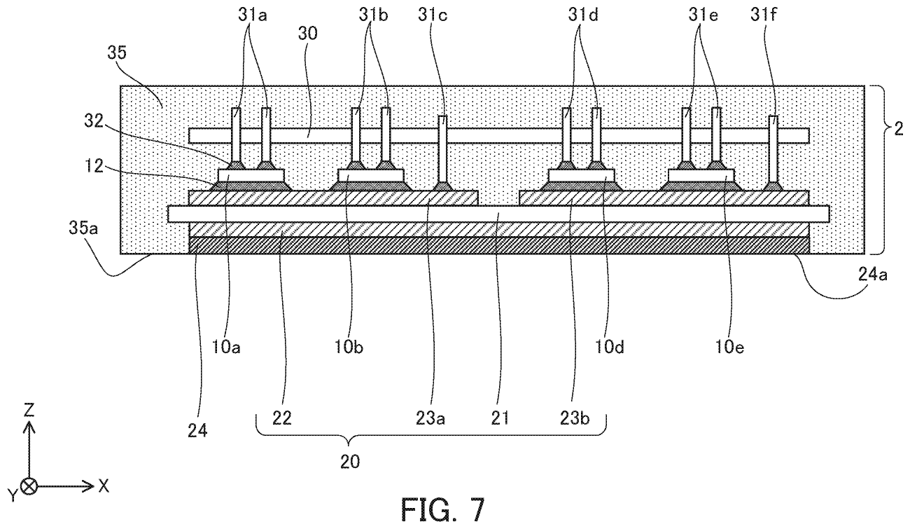

As the last step of process P2, sealing is performed with the sealing member 35 (step P2d). The step P2d will be described with reference to FIGS. 7 and 2. FIG. 7 is a sectional side elevation view of the semiconductor module according to the embodiment. FIG. 2 is a view of the back surface (heat dissipation surface 24a and the sealing lower surface 35a) of the semiconductor module 2 of FIG. 7 viewed in the +Z direction and is a plan view of the heat dissipation surface 24a and the sealing lower surface 35a of the semiconductor module 2.

The structure obtained in the step P2c is set, for example, in a predetermined metal mold. The metal mold is filled with the sealing member 35 to seal the structure. By removing the metal mold, the semiconductor module 2 illustrated in FIG. 7 is obtained. With the semiconductor module 2, as illustrated in FIG. 2, the heat dissipation surface 24a of the stress relaxation layer 24 is exposed from the sealing lower surface 35a of the sealing member 35. The sealing lower surface 35a of the sealing member 35 and the heat dissipation surface 24a of the stress relaxation layer 24 are flush with each other. The back surface of the semiconductor module 2 is made up of the sealing lower surface 35a of the sealing member 35 and the heat dissipation surface 24a of the stress relaxation layer 24.

Next, an application process for applying the bonding member 4 is performed (process P3). The bonding member 4 may be applied to either the back surface (heat dissipation surface 24a and the sealing lower surface 35a) of the semiconductor module 2 or the placement surface 3a of the cooling module 3.

Next, a fixing process for fixing the heat dissipation surface 24a of the stress relaxation layer 24 of the semiconductor module 2 and the sealing lower surface 35a to the placement surface 3a of the cooling module 3 via the bonding member 4 is performed (process P4). First, the cooling module 3 with the bonding member 4 applied to the placement surface 3a is fixed on a predetermined fixing base and the semiconductor module 2 is set on the bonding member 4 applied to the cooling module 3 from the sealing lower surface 35a side.

Furthermore, a structure including the cooling module 3 and the semiconductor module 2 arranged in this way on the placement surface 3a of the cooling module 3 via the bonding member 4 is heated. At this time heating temperature is, for example, 200° C. or less. Because the heating temperature is lower than the melting temperature of the solders 12 and 32, remelting of the solders 12 and 32 in the semiconductor module 2 is suppressed. In addition, at this time the semiconductor module 2 is pressed toward the cooling module 3 at a constant pressure. By doing so, the thickness of the bonding member 4 is controlled. By performing heating in this way, the bonding member 4 is cured and the semiconductor module 2 and the cooling module 3 are bonded together. As a result, the semiconductor device 1 illustrated in FIGS. 1 and 2 is obtained.

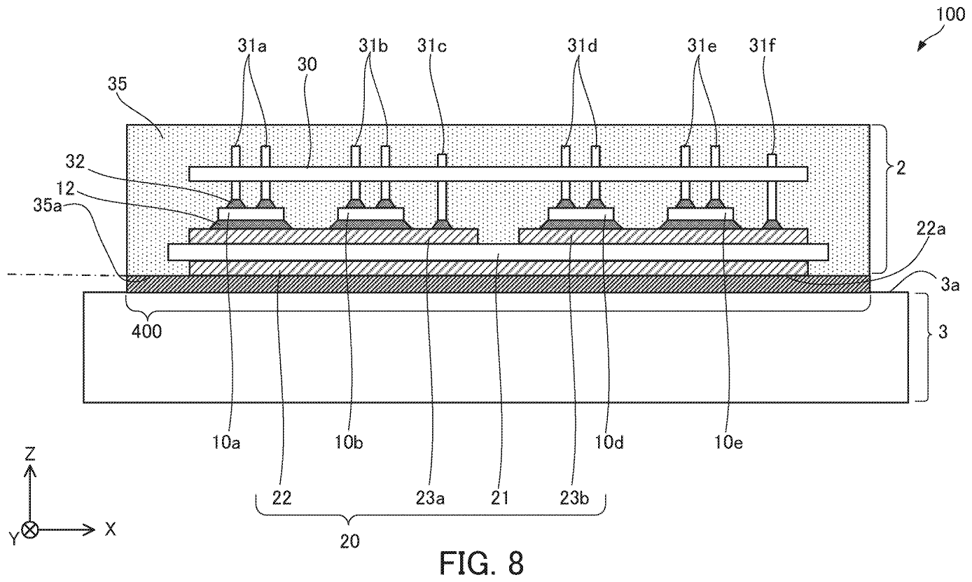

A semiconductor device 100 taken as a reference example will be described with reference to FIG. 8. FIG. 8 is a sectional side elevation view of a semiconductor device taken as a reference example. A semiconductor module 2 of a semiconductor device 100 taken as a reference example is a case where the semiconductor module 2 of the semiconductor device 1 does not include the stress relaxation layer 24. That is to say, the semiconductor device 100 has the same structure as the semiconductor device 1 except for the stress relaxation layer 24.

Furthermore, a bonding member 400 may be a thermal interface material (hereinafter, TIM). However, the bonding member 400 is different from the bonding member 4 in the embodiment. The TIM used is an insulating material such as thermally conductive grease, an elastomer sheet, room temperature vulcanization (RTV) rubber, gel, or a phase change material. In addition, the bonding member 400 is in contact with an entire heat dissipation surface 22a of a metal plate 22 of the semiconductor module 2 and an entire sealing lower surface 35a to bond the semiconductor module 2 and a cooling module 3 together.

The components included in the semiconductor module 2 included in the semiconductor device 100 have different linear expansion coefficients. Therefore, due to heating and cooling in the course of manufacturing the semiconductor module 2 and a heat cycle at the time of the use of the semiconductor device 100, the semiconductor module 2 and the cooling module 3 are warped and deformed. As a result, stress is applied to the bonding member 400 between the semiconductor module 2 and the cooling module 3. If the bonding member 400 is in the form of grease, then the bonding member 400 receives stress and is pushed out from between the semiconductor module 2 and the cooling module 3, each time the semiconductor module 2 and the cooling module 3 are deformed. If the bonding member 400 in the form of a sheet, then peeling occurs between the semiconductor module 2 and the cooling module 3. If the bonding member 400 is an adhesive, then a crack appears and peeling occurs between the semiconductor module 2 and the cooling module 3. Therefore, when stress is applied to the bonding member 400 in this way, thermal conductivity between the semiconductor module 2 and the cooling module 3 deteriorates and the heat dissipation property of the semiconductor module 2 deteriorates.

On the other hand, the semiconductor device 1 includes the insulated circuit board 20 including the metal plate 22 in the lowermost layer, the stress relaxation layer 24 formed on the lower surface of the metal plate 22 and having a linear expansion coefficient larger than that of the metal plate 22, and the cooling module 3 including the placement surface 3a on which the lower surface of the stress relaxation layer 24 is arranged via the bonding member 4 which is a thermally conductive adhesive. Because the stress relaxation layer 24 has a larger linear expansion coefficient than the metal plate 22, the difference in linear expansion coefficient between the metal plate 22 (insulated circuit board 20) and the placement surface 3a of the cooling module 3 decreases by stages. Therefore, because the amount of a warp of the entire semiconductor module 2 decreases, stress applied to the bonding member 4 also decreases. Furthermore, because the bonding member 4 has an adhesive property, the cooling module 3 is stuck to the semiconductor module 2. As a result, a decrease in thermal conductivity between the semiconductor module 2 and the cooling module 3 is reduced and deterioration in the heat dissipation property of the semiconductor module 2 is prevented.

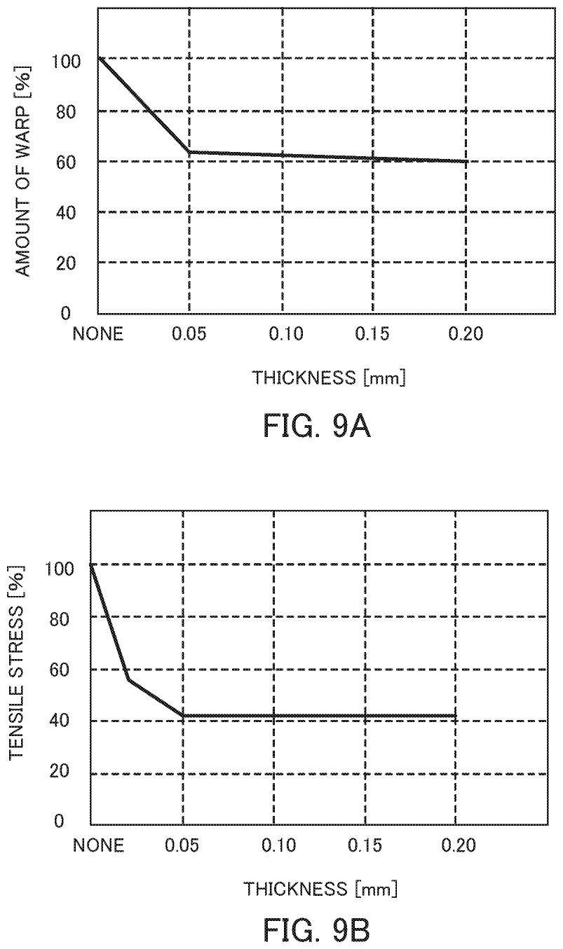

The amount of a warp and tensile stress of the insulated circuit board 20 according to the thickness of the bonding member 4 will now be described with reference to FIGS. 9A and 9B. FIGS. 9A and 9B are graphs indicative of the amount of a warp and tensile stress, respectively, according to the thickness of a stress relaxation layer. FIG. 9A illustrates the amount of a warp of the insulated circuit board 20 according to the thickness of the bonding member 4. In FIG. 9A, the horizontal axis represents the thickness [mm] of the bonding member 4 and the vertical axis represents the amount of a warp [%]. In this case, the amount of a warp is, for example, the distance from the lower surface of the insulated circuit board 20 before the warp occurs to the top of the upward convex upper surface of the insulated circuit board 20 after the warp occurs if the upper surface (conductive circuit patterns 23a and 23b side) of the insulated circuit board 20 faces upward and an upward convex warp occurs. Furthermore, FIG. 9A illustrates the amount of a warp if temperature at the time of bonding by the bonding member 4 is set to 175° C. and is lowered to 25° C., which is normal temperature.

In addition, FIG. 9B illustrates tensile stress applied to the insulated circuit board 20 according to the thickness of the bonding member 4. In FIG. 9B, the horizontal axis represents the thickness [mm] of the bonding member 4 and the vertical axis represents tensile stress [%].

Furthermore, in both cases of FIGS. 9A and 9B, if the stress relaxation layer 24 is not formed, it is represented as “none” on the leftmost side of the horizontal axis. In addition, it is assumed that the amount of a warp and tensile stress of the insulated circuit board 20 in a case where the stress relaxation layer 24 is not formed are each 100%.

First, according to FIG. 9A, if the thickness of the bonding member 4 is increased to 0.05 mm, then the amount of a warp of the insulated circuit board 20 decreases to about 60%. Even if the thickness of the bonding member 4 is increased to 0.2 mm, no further significant decrease in the amount of a warp is observed and the amount of a warp is approximately constant.

Furthermore, according to FIG. 9B, if the thickness of the bonding member 4 is increased to 0.025 mm, then tensile stress applied to the insulated circuit board 20 decreases to about 57%. If the thickness of the bonding member 4 is further increased to 0.05 mm, then tensile stress applied to the insulated circuit board 20 decreases to 40%. On the other hand, even if the thickness of the bonding member 4 is increased to 0.2 mm, no further significant decrease in tensile stress is observed and tensile stress is approximately constant.

As described above, in the semiconductor device 1, the stress relaxation layer 24 having a linear expansion coefficient larger than that of the metal plate 22 is formed between the insulated circuit board 20 and the cooling module 3. By doing so, the amount of a warp of the insulated circuit board 20 and tensile stress applied to the insulated circuit board 20 are decreased even if a thermal change occurs. In particular, the thickness of the stress relaxation layer 24 is preferably 0.025 mm or more and 0.2 mm or less, and more preferably 0.05 mm or more.

According to the disclosed techniques, a decrease in thermal conductivity is suppressed by reducing stress between the board and the cooling module.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit board including a metal plate on a lowermost side thereof;
a stress relaxation layer formed on a lower surface of the metal plate and having a linear expansion coefficient larger than that of the metal plate; and
a cooling module including a placement surface on which a lower surface of the stress relaxation layer is arranged via a thermally conductive adhesive.

2. The semiconductor device according to claim 1, wherein the stress relaxation layer contains aluminum.

3. The semiconductor device according to claim 1, wherein a bonding temperature of the thermally conductive adhesive is 200° C. or lower.

4. The semiconductor device according to claim 1, wherein the thermally conductive adhesive contains an epoxy-based resin having a filler therein.

5. The semiconductor device according to claim 4, wherein the filler is formed of an electrically conductive material.

6. The semiconductor device according to claim 1, wherein the placement surface of the cooling module is made of copper or aluminum, or both.
